(19) United States
(12) Patent Application Publication
(10) Pub. No.: US 2025/0098550 A1
(43) Pub. Date: Mar. 20, 2025

(54) QUANTUM DEVICE AND METHOD OF MANUFACTURING SAME

(71) Applicant: NEC Corporation, Minato-ku, Tokyo (JP)

(72) Inventors: Katsumi KIKUCHI, Tokyo (JP); Satoshi TSUKIYAMA, Tokyo (JP); Tomohiro NISHIYAMA, Tokyo (JP)

(73) Assignee: NEC Corporation, Minato-ku, Tokyo (JP)

(21) Appl. No.: 18/670,767

(22) Filed: May 22, 2024

(30) Foreign Application Priority Data
Sep. 20, 2023 (JP) 2023-151888

(51) Int. Cl. H10N 60/81; H10N 60/01

(52) U.S. Cl. CPC H10N 60/81; H10N 60/01

(57) ABSTRACT

A quantum device using a quantum state, including a quantum chip, a wiring component having a wiring layer, and a laminated substrate installed so that at least the surface of the wiring component on which the quantum chip is mounted is exposed, wherein a wiring layer of the laminated substrate and the wiring layer of the wiring component are connected by an integrated conductor pattern.

This application is based upon and claims the benefit of priority from Japanese patent application No. 2023-151888, filed on Sep. 20, 2023, the disclosure of which is incorporated herein in its entirety by reference.

### TECHNICAL FIELD

The present disclosure relates to a quantum device and a method of manufacturing the same.

### BACKGROUND ART

Japanese Unexamined Patent Application Publication No. 2022-002238 (hereinbelow referred to as Patent Document 1) discloses a quantum device comprising a quantum chip mounted on an interposer, the interposer embedded in a base substrate (e.g., printed circuit board (PCB)), and circuit conductors of the base substrate and circuit conductors of the interposer connected by bonding wires.

This quantum device has the effect of stabilizing the electrical connection at the contact point and maintaining the quality of its signal transmission by suppressing the thermal stress caused by the difference in thermal expansion coefficients of the materials comprising each component (e.g., between the Si (silicon) comprising the interposer and the organic material comprising the PCB).

In the above-mentioned Patent Document 1, since bonding wire is used for connection between the interposer and the base substrate, in addition to the process of patterning by sputtering, evaporation deposition, electroless plating, electrolytic plating and other processes in order to provide a conductor layer on the surface of the base substrate and interposer and form a predetermined circuit pattern, a process using a wire bonding device is required for connection by bonding wire, which is different from the above process of processing the conductor layer to form a predetermined conductor pattern.

In addition, impedance matching is difficult with bonding wire because the connections are individual wires and the distance between the wires as signal and ground circuit types cannot be maintained at the desired distance. Impedance matching is especially important at high frequencies on the order of GHz (gigahertz) and higher.

Therefore, the quantum device described in Patent Document 1 requires a separate manufacturing facility using equipment for an additional bonding process, which increases the cost of the manufacturing facility, and furthermore, the issue arises of suppressing degradation of signal characteristics in the high frequency band that needs to be solved.

### SUMMARY

The purpose of the present disclosure is to simplify the process required to connect the interposer and base substrate of a quantum device.

To solve the aforementioned problems, the present disclosure proposes the following means.

The quantum device according to the first example aspect of the present disclosure is a quantum device using a quantum state, characterized by having a quantum chip, a wiring component having a wiring layer, and a laminated substrate installed so that at least the surface of the wiring component on which the quantum chip is mounted is exposed, and by the wiring layer of the laminated substrate and the wiring layer of the wiring component being connected by an integrated conductor pattern.

The method of manufacturing a quantum device according to the second example aspect of the disclosure is a method of manufacturing a quantum device having a quantum chip, a wiring component having a wiring layer, and a laminated substrate installed so that at least the surface of the wiring component on which the quantum chip is mounted is exposed, characterized by having a process of embedding the wiring component in a recess of the laminated substrate, and a process of connecting the laminated substrate and the wiring component by an integrated conductor pattern.

### Effects of the Disclosure

The present disclosure simplifies the process required to connect the interposer and the base substrate of a quantum device.

### BRIEF DESCRIPTION OF THE DRAWINGS

FIG. 1 is a cross-sectional view showing the minimum configuration of the quantum device according to the present disclosure.

FIG. 2 is a cross-sectional view of the quantum device according to the first example embodiment of the present disclosure.

FIGS. 3A-3D are plan views and cross-sectional views of the quantum device of the first example embodiment of the present disclosure, where FIGS. 3A and 3B show the interposer mounted on the laminated substrate and FIGS. 3C and 3D show the quantum device mounted on the interposer.

FIG. 4 is a cross-sectional view of the quantum device according to the second example embodiment of the present disclosure.

FIG. 5 is a cross-sectional view of the quantum device according to the third example embodiment of the present disclosure.

FIG. 6 is a cross-sectional view of the quantum device according to the fourth example embodiment of the present disclosure.

FIG. 7 is a cross-sectional view of the quantum device according to the fifth example embodiment of the present disclosure.

FIGS. 8A and 8B show the quantum device of the sixth example embodiment of the present disclosure, where FIG. 8A is a plan view and FIG. 8B a cross-sectional view.

FIGS. 9A-9D are enlarged views of the dotted line IX of the quantum device shown in FIGS. 8A and 8B, FIG. 9A being a plan view of chamfer example 1 and FIG. 9B being a plan view of chamfer example 2, FIG. 9C being a cross section of chamfer example 1 and FIG. 9D being a cross section of chamfer example 2.

FIGS. 10A and 10B are plan views of the quantum device of the seventh example embodiment of the present disclosure, wherein FIG. 10A is an example of one quantum device stacked on an interposer and FIG. 10B is an example of multiple quantum devices stacked on an interposer.

FIGS. 11A-11C are plan views of the quantum device according to the eighth example embodiment of the present disclosure, where FIGS. 11A, 11B, and 11C show modification examples 1, 2, and 3 of the range between the quantum device and interposer, respectively.

FIGS. 12A-12C are plan views of the quantum device according to the ninth example embodiment of the present disclosure, where FIGS. 12A, 12B, and 12C show modification examples 1, 2, and 3 of the arrangement of wiring components with respect to the quantum device and interposer, respectively.

### EXAMPLE EMBODIMENT

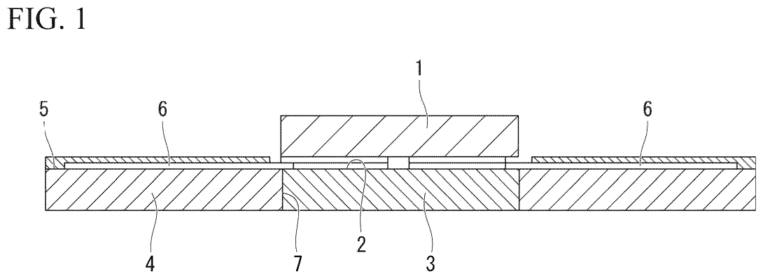

The quantum device according to the minimum configuration example of the present disclosure shall be described with reference to FIG. 1.

This quantum device is a quantum device using a quantum state and has a quantum chip 1, a wiring component 3 having a wiring layer 2, and a laminated substrate 4 installed so that at least the surface of the wiring component 3 on which the quantum chip 1 is mounted is exposed, characterized by the wiring layer 5 of the laminated substrate 4 and the wiring layer 2 of the wiring component 3 being connected by an integral conductor pattern 6.

According to the above configuration, since the wiring layer 2 of the wiring component 3 and the wiring layer 5 of the laminated substrate 4 are connected by the single conductor pattern 6, equipment generally employed in the manufacture of the laminated substrate 4, such as forming a predetermined circuit pattern by using masking with resist, is used for connecting the wiring layer 2 and the wiring layer 5, such that manufacturing can be achieved without the use of wire bonding equipment. In each wiring layer 2 and 5, impedance matching can be achieved to align signal and ground circuits.

The method of manufacturing a quantum device according to the second example aspect of the disclosure is a method of manufacturing a quantum device characterized by having a quantum chip 1, a wiring component 3 having a wiring layer 2, and a laminated substrate 4 installed so that at least the surface of the wiring component 3 on which the quantum chip 1 is mounted is exposed, characterized by having a process of embedding the wiring component 3 in a recess 7 in the laminated substrate 4 and a process of connecting the laminated substrate 4 and the wiring component 3 by means of an integrated conductor pattern 6.

According to the above configuration, by embedding the wiring component 3 in the recess 7 of the laminated substrate 4, the wiring layer 2 of the wiring component 3 and the wiring layer 5 of the laminated substrate 4 can be connected by the integrated conductor pattern 6, and so equipment generally employed in the manufacture of the laminated substrate 4, such as such as trimming, can be used for the connection of the wiring layer 2 and the wiring layer 5, such that manufacturing can be achieved without the use of wire bonding equipment.

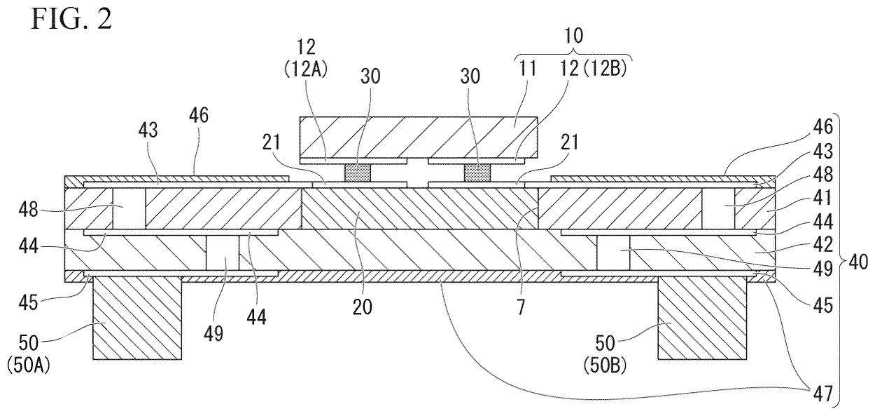

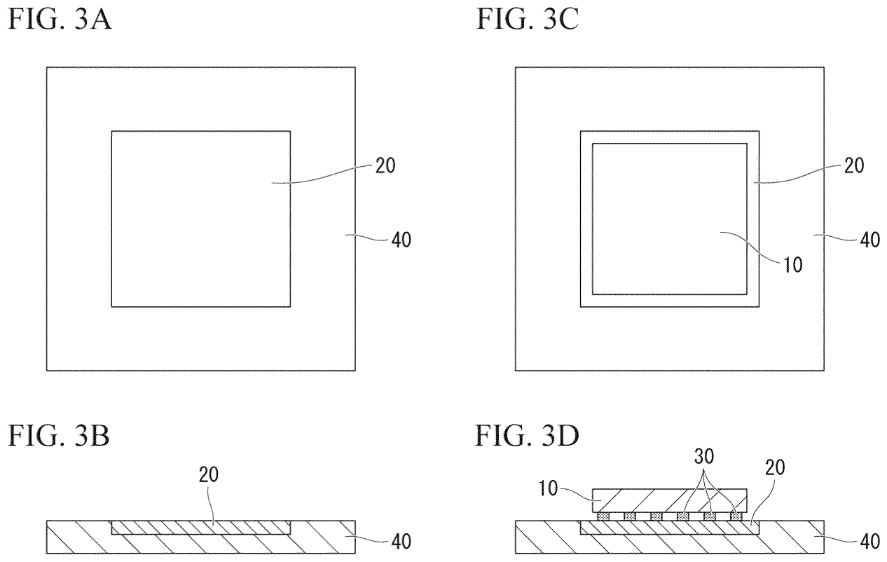

FIG. 2 and FIGS. 3A-3D show the first example embodiment of the present disclosure.

The reference numeral 10 is a quantum chip for quantum computing.

Quantum computing refers to the ability to process data using quantum mechanical phenomena with qubits. The quantum chip 10 is composed of connection portions 12 provided in a predetermined arrangement on the underside of a substrate 11 (each connection portion 12 not necessarily a conductor layer forming a circuit pattern, as long as a conductor can be connected to circuit elements in the quantum chip 10). The connection portion 12 is preferably made of superconducting material.

More specifically, the substrate 11 is composed of a material that is less deformable in a superconducting environment, such as silicon (Si), gallium arsenide (GaAs), sapphire, or glass. Each connection portion 12 comprising the qubit circuit formed on the substrate 11 is made of niobium (Nb), niobium nitride and other niobium nitrides, aluminum (Al), indium (In), lead (Pb), tin (Sn), rhenium (Re), palladium (Pd), titanium (Ti), titanium nitrides, tantalum (Ta), tantalum nitrides, and alloys with superconductivity including at least one of the above.

The aforementioned connection portion 12 may have a metallic layer such as gold (Au), platinum (Pt), or palladium (Pd) formed on the surface as well as the aforementioned superconducting material as the metal of the connection portion in this example embodiment.

The quantum chip 10 is mounted on the wiring component 20 that is connected to the connection portion 12 of the quantum chip 10, and is connected to the wiring layer 21 on the top surface of the wiring component 20 by a bump 30 composed of a conductor. The wiring component 20 is made of a material that has no or as little difference in thermal expansion from the aforementioned quantum chip 10, such as silicon (Si), gallium arsenide (GaAs), sapphire, or glass.

The wiring layer 21 provided on one side (top side in FIGS. 3A-3D) of the wiring component 20 and used for connection with the quantum chip 10 is composed of indium (In), niobium (Nb), niobium nitride such as niobium nitride, titanium (Ti), titanium nitride, tantalum (Ta), tantalum nitride, aluminum (Al), lead (Pb), tin (Sn), or alloys with superconductivity including at least one of these. A metal layer such as gold (Au), platinum (Pt), or palladium (Pd) may also be formed on the surface thereof.

The aforementioned wiring component 20 is inserted into the recess 7, which is recessed from the top surface of the laminated substrate 40 (in detail, passing through only the first substrate 41 among the first substrate 41 and the second substrate 42, described below). The top surface of the wiring component 20 is configured so that the wiring component 20 and the laminated substrate 40 are on the same plane in the illustrated example. The inner diameter dimension of the recess 7 and the outer diameter dimension of the wiring component 20 are set to a dimensional tolerance such that one elastically deforms to an extent of having enough contact pressure to allow relative movement against temperature change, or a small gap can be secured regardless of temperature change.

The underside of the wiring component 20 is not equipped with the wiring layer 21, so the substrate thereof is exposed and in direct contact with the top surface of the laminated substrate 40. The aforementioned wiring component 20 essentially serves as an interposer between the conductor formed at the wiring density of the contact portion with the fine element of the quantum chip 10 and the laminated substrate 40 having the wiring layer of the circuit pattern formed in a general wiring density.

The laminated substrate 40 has a basic configuration consisting of a laminated first substrate 41 and a second substrate 42 made of insulating material, and the first and second substrates 41 and 42 have wiring layers 43, 44, 45 composed of conductors that form a predetermined circuit pattern on the surfaces thereof. The aforementioned wiring layer 43 is covered by an insulating layer 46 formed by, for example, solder resist and passivation film, except for the connection points with the aforementioned quantum chip 10. The aforementioned wiring layer 45 is covered by an insulating layer 47 formed by, for example, solder resist and passivation film, except for the connection points with external devices.

The first substrate 41 has a first interlayer via 48 that passes through it, and the first interlayer via 48 electrically connects the wiring layer 43 on the top surface of the first substrate and the wiring layer 44. The second substrate 42 has a second interlayer via 49 through it, which electrically connects the wiring layer 44 between the first and second substrates 41 and 42 and the wiring layer 45 on the underside of the second substrate 42.

Furthermore, the second substrate 42 is equipped, in the wiring layer 45 on the underside thereof, with a connector 50 provided with terminals in a predetermined arrangement that connect the wiring component 20 to the circuitry of an external device via the wiring layers 43, 44, 45.

In the first example embodiment (as well as in the other example embodiments described below), the quantum chip 10 is provided with two connection portions 12A and 12B, wherein the (first) connection portion 12A is connected to the (first) connector 50 (50A) via the bump 30, the wiring layer 21, the wiring layer 43, the first interlayer via 48, the wiring layer 44, the second interlayer via 49, and the wiring layer 45, all located to the left of the center of FIG. 2, and the (second) connection portion 12B is connected to the (second) connector 50 (50B) via the bump 30, the wiring layer 21, the wiring layer 43, first interlayer via 48, the wiring layer 44, the second interlayer via 49, and the wiring layer 45, all located to the right of the center in FIG. 2. In other words, the quantum chip 10 can transfer data individually to and from devices connected to the first connector 50A and the second connector 50B.

The aforementioned quantum chip 10 and the wiring component 20 have a configuration in which the wiring component 20 is placed in the recess 7 of the laminated substrate 40 as shown in FIG. 3A, and the depth of the recess 7 and thickness of the wiring component 20 are set so that their top surfaces are flush, as shown in FIG. 3B.

On top of the wiring component 20 arranged on the laminated substrate 40 in this manner, the quantum chip 10 is mounted, which is formed in the same shape in plan view (i.e., a shape in which the entirety overlaps vertically) or in a slightly smaller shape in plan view (overlapping a part of the wiring component 20) as shown in FIGS. 3C and 3D, and these are connected by the aforementioned bumps 30.

The wiring layers 43, 44, and 45 of the laminated substrate 40 are composed of materials such as copper (Cu) and aluminum (Al), for example, and are formed into predetermined circuit patterns by means of sputtering, vapor deposition, electroless plating, electrolytic plating, or the like. As specific methods for forming layers of conductive materials into a predetermined circuit pattern, the subtractive method using a resist coated on the surface as a mask, the additive method using plating, the SEMI additive method, and the lift-off method in which the pattern is formed by removing the coated resist, and the like can be applied.

As a method of forming the insulating layers 46 and 47, well-known methods can be applied, such as forming the insulating layers by solder resist or selectively providing insulating properties to some areas by passivation.

The aforementioned first substrate 41 and the second substrate 42 may be composed of organic plastic alone, inorganic or organic fillers, or reinforcing materials such as glass cloth impregnated or laminated with organic plastic.

In the first example embodiment of the above configuration, the quantum device can be manufactured by placing the wiring component 20 on which the quantum chip 10 is mounted by bumps 30 into the recess 7 of the laminated substrate 40, and then forming the wiring layer 43 across these wiring component 20 and the laminated substrate 40.

Here, since the aforementioned wiring layer 43 can be formed by manufacturing to form a general circuit pattern as described above, a quantum device with the quantum chip 10 can be manufactured without a wire bonding process. In each wiring layer, impedance matching can be achieved to align signal and ground circuits.

Since the wiring component 20 is housed in the recess 7 of the laminated substrate 40, the thermal expansion and contraction difference between the wiring component 20 and the laminated substrate 40 due to temperature changes necessary for the operation of quantum devices utilizing the superconductivity phenomenon is absorbed by the gap between the wiring component 20 and the recess 7, or by elastic deformation to the degree that does not cause excessive thermal stress, thereby preventing damage or deterioration of the quantum chip 10 and the wiring component 20.

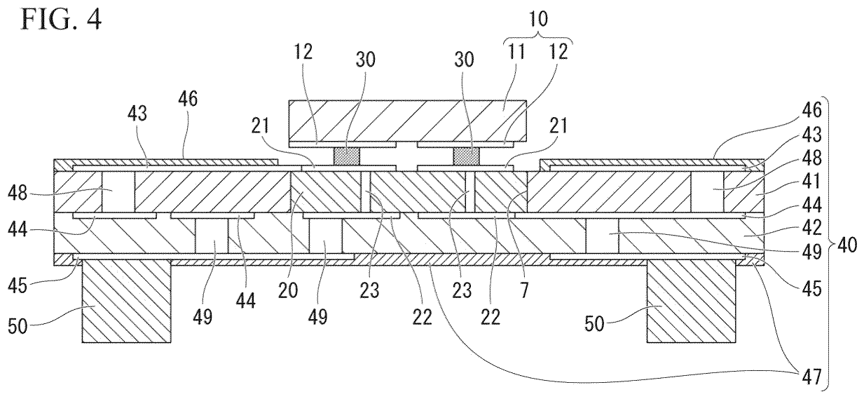

The second example embodiment of the present disclosure shall be described with reference to FIG. 4. In the figure, the same symbols are used for the common components as in FIGS. 2 and 3 to simplify the explanation.

In this second example embodiment, the wiring component 20 is provided with wiring layers 21 and 22 on the front surface (the surface on the side of the quantum chip 10) and the back surface (the surface of the opposite side), as well as a connecting conductor 23 that penetrates the wiring component 20 and electrically connects the front and back wiring layers 21 and 22.

The wiring layer 22 on the back surface is connected to the wiring layer 45 on the back surface of the second substrate 42 via the second interlayer via 49.

In this second example embodiment, the wiring component 20 is connected not only to the front surface of the first substrate 41, which constitutes the laminated substrate 40, but also to the wiring layer 44 between the first substrate 41 and the second substrate 42 via the connecting conductor 23, and further to the wiring layer 45 on the back surface side via the second interlayer via 49.

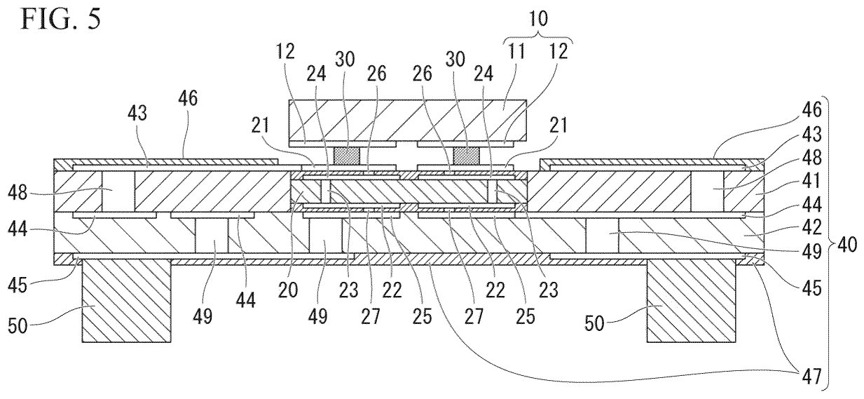

The third example embodiment of the present disclosure shall be described with reference to FIG. 5. In the drawing, the same symbols are used for the common components as in FIGS. 2, 3 and 4 to simplify the explanation.

In this third example embodiment, multiple wiring layers 21 and 24 and wiring layers 22 and 25 are provided on the front and back surfaces, respectively, of the wiring component 20, with the wiring layers 21 and 24 connected by the connection portion 26 and the wiring layers 22 and 25 by the connection portion 27. In this way, the wiring component 20, by being provided with the plurality of wiring layers 21, 24, 22, 25, can connect with the wiring layers 43, 44, 45 of the laminated substrate 40 at more locations, and it is possible to wire and connect between the quantum chip 10 and the equipment connected via the connector 50 at a higher density.

Since countermeasures against energy loss of the qubit circuit are necessary when facing the qubit circuit, and inadequate measures such as shielding with a ground circuit will result in characteristic degradation, it is preferable to mount the quantum chip 10 on a separate component such as an interposer.

In other words, in a qubit circuit (or more precisely, in the resonators and couplers that make up the qubit), performance is directly related to maintaining the quantum state for a long time. The time it takes to maintain this quantum state is called the coherence time, and a long coherence time allows the calculation to continue until the correct answer is reached, resulting in a high final correct answer rate.

Since quantum states disappear when energy loss occurs, it is necessary to avoid placement of dielectric materials that cause energy loss in and near the region of quantum circuits, and so it is desirable to minimize the number of substrates (silicon, sapphire, etc.) on which circuits are installed and avoid placement in areas that are larger than necessary.

Accordingly, it is desirable to avoid bringing dielectric materials close to the circuit surface of the quantum chip 10 with quantum circuits, i.e., the surface where the connection terminals are provided, which means that in the case of flip chips, it is advisable to avoid positioning dielectric materials in close proximity to the surface of the wiring component 20 side.

After mounting on the wiring component 20, by making a suitable connection to ground in the circuit on the side of the wiring component 20 to form a shield, it is possible to relax the restrictions on the placement of the dielectric (insulating material). The shielding configuration of the wiring component 20 allows the use of a dielectric (insulating material) in the laminated substrate 40.

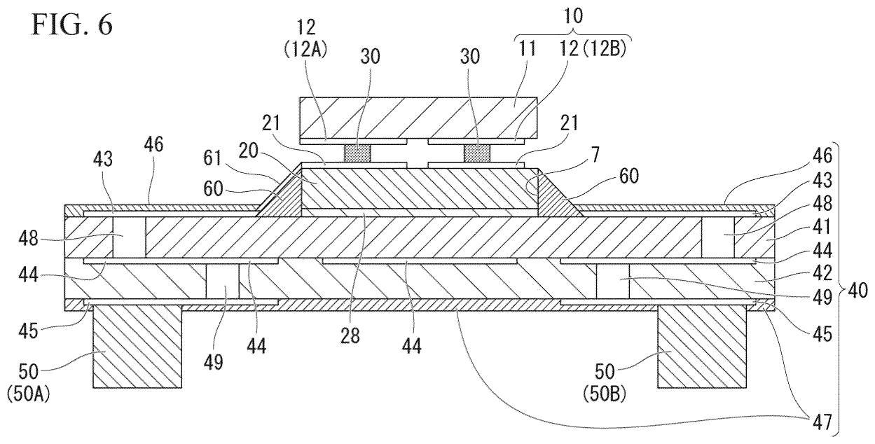

The fourth example embodiment of the present disclosure shall be described with reference to FIG. 6. In the drawing, the same symbols are used for configurations common to FIGS. 2, 3, 4, and 5 to simplify the explanation.

This fourth example embodiment has a fillet 60 protruding from the top surface of the laminated substrate 40. The fillet 60, like the laminated substrate 40, is composed of organic plastic or the like, and is formed by integral molding with the laminated substrate 40 or by adhering to the top surface of the laminated substrate 40 by adhesion or the like.

The fillet 60 has a void that passes through the top and bottom, with the space surrounded by this penetration point and the laminated substrate 40 being the recess 7 that accommodates the wiring component 20, and has a contour shape (generally square or rectangular) that surrounds the recess 7 in plan view.

One side of the fillet 60 has a wiring layer 61, which constitutes a predetermined circuit pattern and connects the wiring layer 43 on the top surface of the laminated substrate 40 and the wiring layer 21 on the top surface of the wiring component 20.

The underside of the wiring component 20 placed inside the fillet 60 is provided with an adhesive layer 28 composed of a metal such as Ag (silver) that serves as a die bond or paste material, for example, and this adhesive layer 28 adheres the wiring component 20 to the top surface of the laminated substrate 40.

Since this fourth example embodiment has the fillet 60 on the top surface of the laminated substrate 40, a flat standard substrate is used as the laminated substrate 40, and by additionally attaching the fillet 60 on the top surface thereof, the recess 7 that accommodates the wiring component 20 can be provided on the top surface of the laminated substrate 40 and, similarly to the aforementioned first to third example embodiments, it can be manufactured without the use of wire bonding equipment. In addition, as the wiring layers 43˜61˜21 are formed across the surface of the laminated substrate 40 and the surface of wiring component 20 and electrically connected, the wiring layer 61 between the wiring layers 21 and 46 can be supported from below by the fillet 60, and so even if, for example, a thermal expansion difference occurs between the laminated substrate 40, the fillet 60 and the wiring component 20, it is possible to prevent disconnection by reinforcing the wiring layer 61.

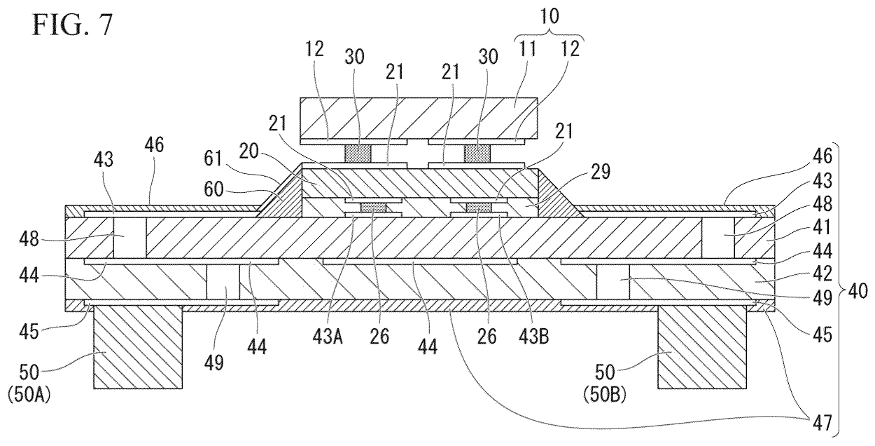

The fifth example embodiment of the present disclosure shall be described with reference to FIG. 7. In the drawing, the same symbols are attached to the common configuration as in FIGS. 2, 3, 4, 5, and 6 to simplify the explanation.

This fifth example embodiment has a configuration in which the wiring layer 21 on the underside of the wiring component 20 and the wiring layers 43A and 43B of the laminated substrate 40 below it are connected by connection portions 26 each consisting of a metal bump. Between the aforementioned wiring layer 21 and the wiring layers 43A and 43B, an underfill portion 29 is formed by injecting synthetic resin.

In this fifth example embodiment, by utilizing the two wiring layers 21 and 25 on the front and back of the wiring component 20, connections with the wiring layers 43A, 43B, etc. of the laminated substrate 40 can be made at more connection points.

Organic resins are mainly applied to the aforementioned adhesive layer 28, underfill portion 29, and fillet 60.

Examples of this organic resin include epoxy resin, acrylic resin, urethane resin, styrene resin, polyimide, polyamide, and oxazole. For example, it is also effective to simplify the manufacturing process by using the same organic resin for the fillet 60 and the adhesive layer 28 of the fourth example embodiment, or by using the same organic resin for the underfill portion 29 and the fillet 60 of the fifth example embodiment, and forming them in the same manufacturing process.

These organic resins may be mixed with inorganic or organic fillers (reinforcing fibers) to adjust the coefficient of thermal expansion for the purpose of preventing warpage, to reduce shrinkage when the organic resins cure, and to prevent cracking and its propagation over time. Similarly, different types of organic resins may be mixed or laminated (pasted) together.

The exposed surface of the wiring component 20 and the terminal electrode or wiring layer on the wiring component 20 side of the laminated substrate 40 may be electrically connected by printing conductive paste or inkjet printing. The number of substrate layers, the number of wiring layers, and the number of connectors constituting the aforementioned laminated substrate 40 are of course not limited to the example embodiment.

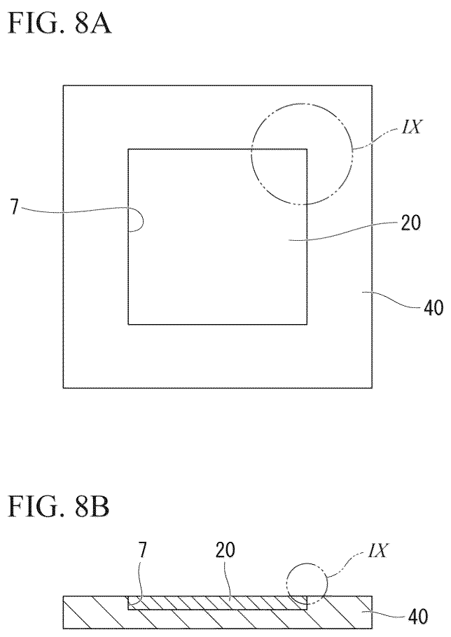

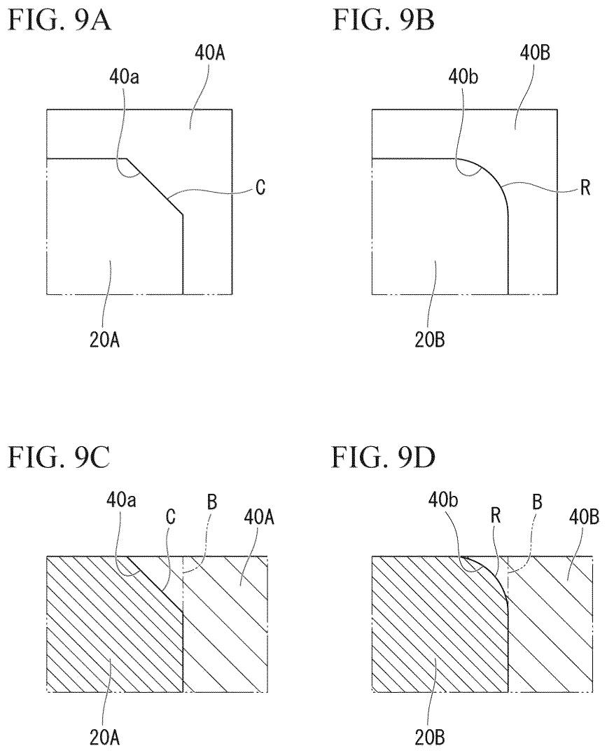

FIGS. 8 and 9 show the sixth example embodiment of the present disclosure. This sixth example embodiment of the quantum device has features that can be applied to any of the above first to fifth example embodiments, and has a common configuration with the first to fifth example embodiments, except where the configuration is specifically detailed. In other words, it can be implemented in combination with any of the first through fifth example embodiments.

As shown in FIGS. 8A and 8B, the wiring components 20 are located in the recess 7 of the laminated substrate 40. The wiring component 20 and the laminated substrate 40 are manufactured based on predetermined dimensional tolerances to allow the wiring component 20 and the laminated substrate 40 to slide and move relative to each other, with care taken to reduce the thermal stress caused by the difference in thermal contraction due to the temperature difference between the low temperature required for superconductivity and the room temperature during manufacturing.

Furthermore, in this sixth example embodiment, as shown in FIGS. 9A and 9C, which is an enlargement of the IX portion of FIGS. 8A and 8B, as chamfer example 1, a sloping surface chamfer 40a is applied to the concave portion of the corners of laminated substrate 40A, which is an example modification of the above-mentioned laminated substrate 40. The corresponding corners of the wiring component 20 also have the same or slightly longer sloping chamfer C. In other words, by forming the chamfer C, it is easier for the two to slide and move relative to each other, compared to sharp corners without chamfers, making it difficult for thermal stress to concentrate in that area and preventing chipping due to stress concentration.

In other words, the formation of the chamfer C prevents the phenomenon of chipping in that area due to thermal stress, compared to sharp corner corners without chamfers.

In detail, the presence of the chamfer C makes the angle between the outer surface corner between one outer surface of the wiring component 20 and the other outer surface orthogonal to that one, and the inner surface corner between one inner surface of the laminated substrate 40 and the other inner surface orthogonal to that one, an obtuse angle greater than the orthogonal angle, so that relative movement becomes easier than in the orthogonal case, and chipping due to the above thermal stress can be prevented.

As shown in FIGS. 9B and 9D, which is an enlargement of the IX portion of FIGS. 8A and 8B, as chamfer example 2, a curved chamfer 40b with a predetermined radius of curvature is applied to the recesses at the corners of the laminated substrate 40B, which is a modification example of the above-mentioned laminated substrate 40. The corresponding corners of the wiring component 20 also have a curved chamfer R with the same or slightly smaller radius of curvature. In other words, by forming the chamfer R, it is easier for the two to slide and move relative to each other compared to the case where the corner is left sharp without chamfering, and stress caused by thermal expansion and contraction is less likely to be concentrated in that area, thereby preventing chipping of the substrate and other parts.

In detail, due to the presence of the chamfer R, similarly to the case in which the angle between the outer surface corner between one outer surface of the wiring component 20 and the other outer surface orthogonal to that one, and the inner surface corner between one inner surface of the laminated substrate 40 and the other inner surface orthogonal to that one becomes an obtuse angle greater than the orthogonal angle, relative movement becomes easier than in the orthogonal case, and chipping due to the above thermal stress can be prevented.

In addition, a configuration that prevents contact between the wiring components 20A and 20B and laminated substrates 40A and 40B by removing the laminated substrates 40A and 40B in the area between the dotted line B in FIGS. 9C and 9D and the wiring components 20A and 20B (the area indicated by the abbreviated triangle in the same figure) may be adopted.

The processing points to avoid chipping of the corners of the wiring components 20A, 20B, due to relative movement of the corners against the inner surfaces of the laminated substrates 40A, 40B, by processing that forms the chamfer C or chamfer R described in the sixth example embodiment above, or the processing that removes the area indicated by the above dotted line B, or processing similar to these shall be referred to as relief portions.

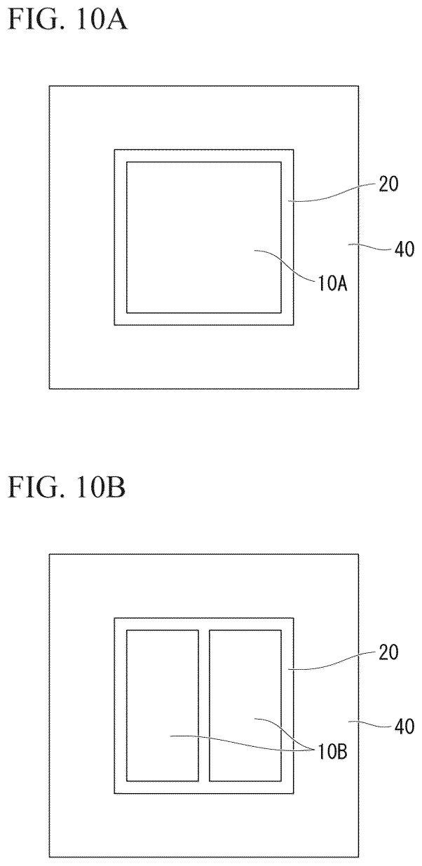

FIGS. 10A and 10B show the seventh example embodiment of the present disclosure.

The quantum device of arrangement example 1 shown in FIG. 10A has a configuration in which a similarly square-shaped wiring component 20 is placed in the center of a square-shaped laminated substrate 40 in plan view, and a square-shaped quantum chip 10A with a contour slightly smaller than that of the wiring component 20 is placed in the center of the wiring component 20.

The quantum device of arrangement example 2 shown in FIG. 10B has a configuration in which a similar square-shaped wiring component 20 is placed in the center of a square-shaped laminated substrate 40 in plan view, and two rectangular-shaped quantum chips 10B are placed over the wiring component 20 in line symmetry. The rectangular-shaped quantum chips 10B have the shape obtained by dividing into two a square that is slightly smaller than the aforementioned wiring component 20.

As shown in the arrangement examples 1 and 2 of this seventh example embodiment, the quantum chip 10A provided on one wiring component 20 may be singular or plural. When multiple quantum chips 10B are provided as shown in FIG. 10B, these quantum chips 10B can be connected to each other by the wiring layers of the aforementioned wiring component 20 or individually to the laminated substrate 40. The number of wiring components 20 mounted on one laminated substrate 40 or the number of quantum chips 10A mounted on one wiring component 20 is of course not limited to the arrangement examples 1 and 2 shown in FIGS. 10A and 10B.

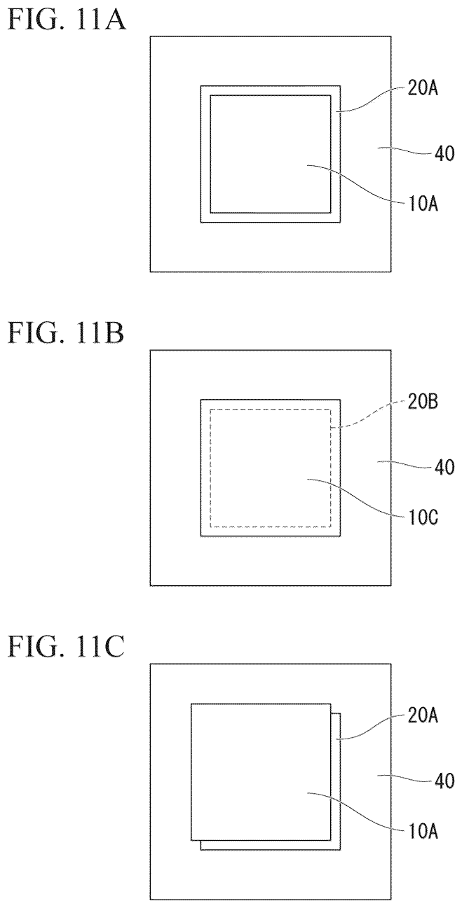

FIGS. 11A-11C show the eighth example embodiment of the present disclosure.

The quantum device of arrangement example 3 shown in FIG. 11A has a configuration in which a wiring component 20A with an approximately similar square shape is arranged in the center of a square-shaped laminated substrate 40 in plan view, and a square-shaped quantum chip 10A with a contour slightly smaller than that of the wiring component 20A is arranged in the center of the wiring component 20A (substantially the same configuration as in Arrangement Example 1 shown in FIG. 10A).

The quantum device of arrangement example 4 shown in FIG. 11B has a configuration in which a wiring component 20B with an approximately similar square shape is arranged in the center of a square-shaped laminated substrate 40 in plan view, as shown by the dashed line in the same figure, and further, on the wiring component 20B, a quantum chip 10C with an approximately similar square shape that is slightly larger than the wiring component 20B and smaller in outline than the abovementioned laminated substrate 40, is arranged.

In this arrangement example 4, a conductor that serves as a connection portion is placed only in the area of the quantum chip 10C that overlaps the aforementioned wiring component 20B in plan view.

The quantum device of arrangement example 5 shown in FIG. 11C has a configuration in which a wiring component 20A with an approximately similar square shape is arranged in the center of a square-shaped laminated substrate 40 in plan view, and moreover a square-shaped quantum chip 10A identical to the wiring component 20A is arranged on top of the wiring component 20A, and a configuration in which a portion of the quantum chip 10A is arranged overlapping the wiring component 20A.

In this arrangement example 5, the conductor that serves as the connection portion is placed only in the area where the quantum chip 10A overlaps the wiring component 20A in plan view.

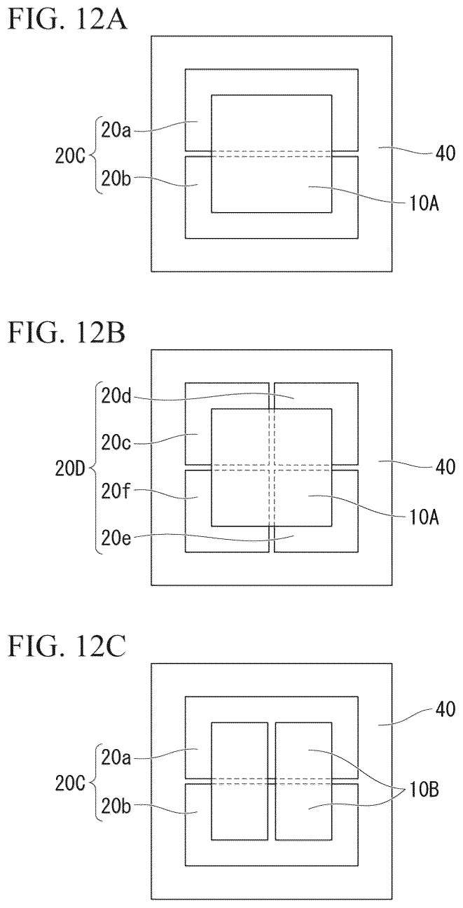

FIGS. 12A-12C show the ninth example embodiment of the present disclosure.

The quantum device of division example 1 shown in FIG. 12A has a configuration in which in the center of a square-shaped laminated substrate 40 in plan view are placed divided wiring components 20a and 20b with rectangular shapes formed by dividing into two an approximately similarly square shape, whereby an overall wiring component 20C having a square shape that is approximately similar to the laminated substrate 40 mounted. The quantum chip 10A is mounted on top of the wiring component 20C, spanning the aforementioned divided wiring components 20a and 20b.

The quantum device of division example 2 shown in FIG. 12B has a configuration in which in the center of the square-shaped laminated substrate 40 in plan view are placed divided wiring components 20c, 20d, 20e, and 20f with square shapes formed by dividing into four an approximately similarly square shape, whereby an overall wiring component 20D having a square shape that is approximately similar to the laminated substrate 40 mounted. The quantum chip 10A is mounted on top of the wiring component 20D, spanning the aforementioned divided wiring components 20c, 20d, 20e, and 20f.

The quantum device of division example 2 shown in FIG. 12C has a configuration in which in the center of the square-shaped laminated substrate 40 in plan view are placed divided wiring components 20a and 20b with rectangular shapes formed by dividing into two an approximately similarly square shape, whereby an overall wiring component 20C having a square shape that is approximately similar to the laminated substrate 40 mounted. Rectangular-shaped quantum chips 10B are mounted on top of the wiring component 20C, spanning the aforementioned divided wiring components 20a and 20b. The rectangular-shaped quantum chips 10B have the shape obtained by dividing into two a square that is slightly smaller than the aforementioned wiring component 20.

In the above division examples 1, 2, and 3, the divided wiring components 20a, 20b, or the divided wiring components 20c, 20d, 20e, and 20f are used as the wiring components 20C or 20D, respectively, so compared to the wiring components of the other example embodiments, which have an integrated configuration, the divided wiring components 20a and 20b, or the divided wiring components 20c, 20d, 20e, and 20f, can move relative to each other, and this relative movement allows the thermal stress caused by temperature changes to be smaller than in the case of the integrated configuration.

The aforementioned quantum chips 10B also have a rectangular shape obtained by dividing a predetermined square shape into two parts, which allows their relative movement and reduces thermal stress compared to the case of being constituted as a single unit.

The shape, number of divisions, and arrangement in plan view of the aforementioned laminated substrate, wiring components, and quantum devices are not limited to each arrangement or division example.

While preferred example embodiments of the disclosure have been described and illustrated above, it should be understood that these are exemplary of the disclosure and are not to be considered as limiting. Additions, omissions, substitutions, and other modifications can be made without departing from the scope of the present disclosure. Accordingly, the disclosure is not to be considered as being limited by the foregoing description, and is only limited by the scope of the appended claims.

Some or all of the above example embodiments may also be described in the following supplementary notes, but are not limited to the example aspects identified in the supplementary notes.

### (Supplementary Note 1)

A quantum device using a quantum state, including:
a quantum chip;
a wiring component having a wiring layer; and
a laminated substrate installed so that at least the surface of the wiring component on which the quantum chip is mounted is exposed,
wherein the wiring layer of the laminated substrate and the wiring layer of the wiring component are connected by an integrated conductor pattern.

### (Supplementary Note 2)

The quantum device according to Supplementary Note 1, wherein the wiring component is embedded in the laminated substrate.

### (Supplementary Note 3)

The quantum device according to Supplementary Note 2, further including a relief portion at at least either one of an outer surface corner between one outer surface of the wiring component and another outer surface that intersects that one outer surface, and an inner surface corner between one inner surface of the laminated substrate and another inner surface that intersects that one inner surface.

### (Supplementary Note 4)

The quantum device according to any one of Supplementary Notes 1 to 3, wherein the conductor pattern includes a portion of a conductor layer on the surface of the laminated substrate.

### (Supplementary Note 5)

The quantum device according to any one of Supplementary Notes 1 to 4, further including the wiring component having a plurality of the wiring layers.

### (Supplementary Note 6)

The quantum device according to any one of Supplementary Notes 1 to 5, wherein the wiring component includes a core material and a through-via that penetrates the core material.

### (Supplementary Note 7)

The quantum device according to any one of Supplementary Notes 1 to 6, wherein the wiring component includes a plurality of divided wiring components arranged on the laminated substrate, and the quantum chip is arranged across the divided wiring components.

### (Supplementary Note 8)

The quantum device according to any one of Supplementary Notes 1 to 7, wherein a plurality of the quantum chips are arranged on the single wiring component.

### (Supplementary Note 9)

The quantum device according to any one of Supplementary Notes 1 to 8, wherein all or part of the quantum chip is arranged to overlap the wiring component in plan view.

### (Supplementary Note 10)

The quantum device according to any one of Supplementary Notes 1 to 9, wherein the quantum chip is arranged so as to overlap a plurality of the wiring components in plan view.

### (Supplementary Note 11)

The quantum device according to any one of Supplementary Notes 1 to 10, wherein the laminated substrate has a plurality of wiring layers.

### (Supplementary Note 12)

The quantum device according to any one of Supplementary Notes 1 to 11,
wherein an insulating layer of the laminated substrate is composed of organic materials.

### (Supplementary Note 13)

The quantum device according to any one of Supplementary Notes 1 to 12, characterized by the laminated substrate being provided with a connector.

### (Supplementary Note 14)

The quantum device according to Supplementary Note 13, wherein the laminated substrate has a plurality of connectors, some of the connectors being connected to some circuits of the wiring component, and other connectors being connected to other circuits of the wiring component.

### (Supplementary Note 15)

A method of manufacturing a quantum device including a quantum chip, a wiring component having a wiring layer, and a laminated substrate installed so that at least the surface of the wiring component on which the quantum chip is mounted is exposed, the method including:

embedding the wiring component in a recess of the laminated substrate; and

connecting the laminated substrate and the wiring component by an integrated conductor pattern.

### INDUSTRIAL APPLICABILITY

The present disclosure can be used for quantum devices and the manufacture thereof.

What is claimed is:

1. A quantum device using a quantum state, comprising:
a quantum chip;
a wiring component having a wiring layer;
a laminated substrate installed so that at least the surface of the wiring component on which the quantum chip is mounted is exposed; and
an integrated conductor pattern connecting the wiring layer of the laminated substrate with the wiring layer of the wiring component.

2. The quantum device according to claim 1, wherein the wiring component is embedded in the laminated substrate.

3. The quantum device according to claim 2, further comprising a relief portion at at least either one of an outer surface corner between one outer surface of the wiring component and another outer surface that intersects that one outer surface, and an inner surface corner between one inner surface of the laminated substrate and another inner surface that intersects that one inner surface.

4. The quantum device according to claim 1, wherein the conductor pattern includes a portion of a conductor layer on the surface of the laminated substrate.

5. The quantum device according to claim 1, further comprising the wiring component having a plurality of the wiring layers.

6. The quantum device according to claim 1, wherein the wiring component includes a core material and a through-via that penetrates the core material.

7. The quantum device according to claim 1, wherein the wiring component includes a plurality of divided wiring components arranged on the laminated substrate, and the quantum chip is arranged across the divided wiring components.

8. The quantum device according to claim 1, wherein a plurality of the quantum chips are arranged on the single wiring component.

9. The quantum device according to claim 1, wherein all or part of the quantum chip is arranged to overlap the wiring component in plan view.

10. The quantum device according to claim 1, wherein the quantum chip is arranged so as to overlap a plurality of the wiring components in plan view.

11. The quantum device according to claim 1, wherein the laminated substrate has a plurality of wiring layers.

12. The quantum device according to claim 1, wherein an insulating layer of the laminated substrate is composed of organic materials.

13. The quantum device according to claim 1, wherein the laminated substrate is provided with a connector.

14. The quantum device according to claim 13, wherein the laminated substrate has a plurality of connectors, some of the connectors being connected to some circuits of the wiring component, and other connectors being connected to other circuits of the wiring component.

15. A method of manufacturing a quantum device comprising a quantum chip, a wiring component having a wiring layer, and a laminated substrate installed so that at least the surface of the wiring component on which the quantum chip is mounted is exposed, the method comprising:
embedding the wiring component in a recess of the laminated substrate; and
connecting the laminated substrate and the wiring component by an integrated conductor pattern.
